(19) United States
(12) Patent Application Publication
(10) Pub. No.: US 2008/0093052 A1
(43) Pub. Date: Apr. 24, 2008

(54) HEAT DISSIPATION DEVICE WITH HEAT PIPES

(75) Inventors: PING-AN YANG, Shenzhen (CN); SHI-WEN ZHOU, Shenzhen (CN); CHUN-CHI CHEN, Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Taipei Hsien (TW)

(21) Appl. No.: 11/551,677

(22) Filed: Oct. 20, 2006

(51) Int. Cl. H05K 7/20

(52) U.S. Cl. 165/80.3; 165/104.33; 361/700

(57) ABSTRACT

A heat dissipation device is used for removing heat from an electronic device. The heat dissipation device includes a base adapted for thermally engaging with the electronic device, the base having a top face and defining two juxtaposed, sinuous grooves in the same side as the top face, two flat heat pipes fittingly received in the grooves of the base, and a plurality of fins arranged on the top surface of the base and the flat heat pipes, wherein each of the grooves encloses a first U-shaped region and a second U-shaped region which is smaller than the first U-shaped region. The first and second U-shaped regions have opposite orientations, and the second U-shaped region of one of the grooves is located in the first U-shaped region of another one of the grooves.

### BACKGROUND OF THE INVENTION

1. Field of the Invention

The present invention relates to heat dissipation devices for use in removing heat from electronic devices, and more particularly to a heat dissipation device incorporating heat pipes for improving heat dissipation efficiency of the heat dissipation device.

2. Description of Related Art

During operation of an electronic device such as a computer central processing unit (CPU), a large amount of heat is often produced. The heat must be quickly removed from the CPU to prevent it from becoming unstable or being damaged. Typically, a heat dissipation device is attached to an upper surface of the CPU to absorb heat from the CPU. The heat absorbed by the heat dissipation device is then dissipated to ambient air.

Conventionally, a heat dissipation device comprises a solid metal base attached on the CPU, and a plurality of fins arranged on the base. The base is intimately attached to the CPU thereby absorbing the heat generated by the CPU. Most of the heat accumulated at the base is transferred firstly to the fins and then dissipates away from the fins. However, as electronics technology continues to advance, increasing amounts of heat are being generated by powerful state-of-the-art CPUs. As a result, many conventional heat dissipation devices are no longer able to efficiently remove heat from these CPUs.

In order to overcome the above set out problems, one type of heat dissipation device used with the electronic devices includes a heat pipe for transferring heat from one part to another part of the heat dissipation device. A heat pipe is a vacuum-sealed pipe that is filled with a phase changeable fluid, usually being a liquid, such as water, alcohol, acetone or the like, and has an inner wall thereof covered with a capillary configuration. As the electronic device heats up, a hot section—usually called an evaporating section—of the heat pipe which is located close to the electronic device also heats up. The liquid in the evaporating section of the heat pipe evaporates and the resultant vapor reaches a cool section—usually called a condensing section—of the heat pipe and condenses therein. Then the condensed liquid flows to the evaporating section along the capillary configuration of the heat pipe. This evaporating/condensing cycle repeats and since the heat pipe transfers heat so efficiently, the evaporating section is kept at or near the same temperature as the condensing section of the heat pipe. Correspondingly, heat-transfer capability of the heat dissipation device including such the heat pipe is greatly improved.

For instance, FIG. 3 illustrates a heat dissipation device in accordance with prior art which incorporates two heat pipes 2. The heat dissipation device further comprises a base 1 for contacting with an electronic device and a plurality of fins 3 arranged on the base 1. The base 1 defines two parallel grooves 11 therein. The fins 3 cooperatively define two through holes (not labeled) therein. Each heat pipe 2 has a substantially straight evaporating section 21 received in one of the grooves 11 of the base 1, a straight condensing section 22 substantially parallel to the evaporating section 21 received in one of the through holes of the fins 3, and a connecting section 23 connecting the evaporating section 21 and the condensing section 22. The heat generated by the electronic device is absorbed by the base 1, and transferred from the base 1 to a lower portion of the fins 3 and the evaporating sections 21 of the heat pipes 2. Then the heat is transferred to an upper portion of the fins 3 by the fins 3 themselves and the heat pipes 2, and finally dissipated from the fins 3 to ambient air. However, the connection between the heat pipe 2 and the base 1 is so limited at a central portion of the base 1 that the heat generated by the electronic device generally accumulates in central areas of the base 1, and heat transferred by the evaporating section 21 of the heat pipe 2 is also limited. Consequently, large amounts of the heat accumulate in the center of the base 1. Therefore, the heat dissipation efficiency of the heat dissipation device is not optimal and cannot meet with the high heat dissipation demands on the electronic device.

What is needed, therefore, is a heat dissipation device which can achieve a greater heat-transfer capability and a greater heat dissipation capability.

### SUMMARY OF THE INVENTION

A heat dissipation device in accordance with a preferred embodiment of the present invention is for contacting with a heat generating electronic device to remove heat from the electronic device. The heat dissipation device includes a base adapted for thermally engaging with the electronic device, the base having a top face and defining two juxtaposed, sinuous grooves at the same side as the top face, two flat heat pipes fittingly received in the grooves of the base, and a plurality of fins arranged on the top surface of the base and the flat heat pipes, wherein each of the grooves encloses a first U-shaped region and a second U-shaped region which is smaller than the first U-shaped region; the first and second U-shaped regions have opposite orientations; the second U-shaped region of one of the grooves is located in the first U-shaped region of another one of the grooves.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded, isometric view of a heat dissipation device in accordance with a preferred embodiment of the present invention;

FIG. 2 is an assembled view of FIG. 1; and

FIG. 3 is a partially exploded, isometric view of a heat dissipation device in accordance with related art.

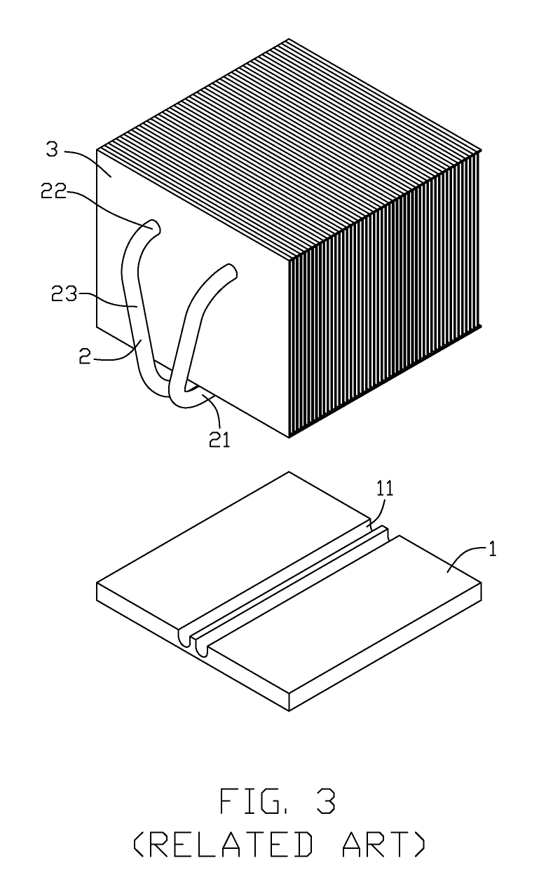

### DETAILED DESCRIPTION OF THE INVENTION

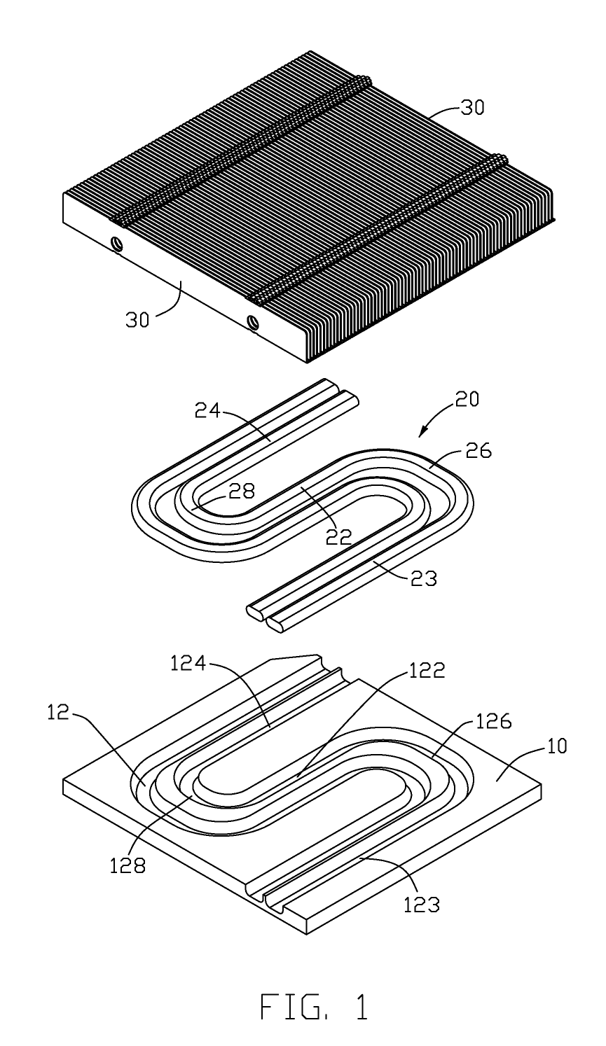

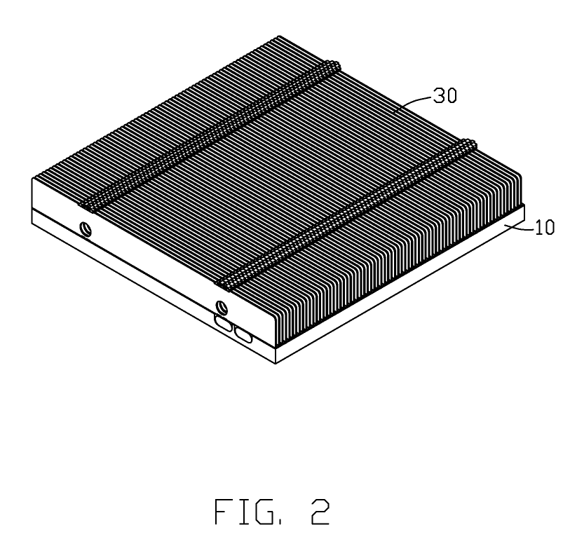

Referring to FIGS. 1 and 2, a heat dissipation device in accordance with a preferred embodiment of the invention comprises a base 10, two heat pipes 20 embedded in the base 10 and a plurality of fins 30 arranged on the base 10.

The base 10 is a substantially rectangular metal plate having good heat conductivity, and has a bottom face (not labeled) for contacting with an electronic device (not shown) and a top face (not labeled) opposing the bottom face. Two substantially S-shaped grooves 12 are defined in the top face of the base 10 for receiving the heat pipes 20 therein.

The two grooves 12 are defined adjacent to each other. Each groove 12 comprises a first linear portion 122, a second linear portion 123, a third linear portion 124, a first arched portion 126 and a second arched portion 128. The first linear portion 122 spans a center of the base 10, the second linear portion 123 is located adjacent to one lateral side of the base 10, the third linear portion 124 is located adjacent to an opposite lateral side of the base 10. The linear portions 122, 123, 124 are each parallel to the two opposite lateral sides of the base 10. The first and second arched portions 126, 128 extend reversely from two opposing ends of the first linear portion 122 and a distance from the first linear portion 122 to the second linear portion 123 is longer than that from the first linear portion 122 to the third linear portion 124. The first arched portions 126 connect the first and the second linear portions 122, 123 together and combine with them to form a first U-shaped region (not labeled), while the second arched portion 128 connects the first and third linear portions 122, 124 and combines with them to form a second U-shaped region (not labeled) which is smaller than the first U-shaped region. The first and second U-shaped regions have opposite orientations. The second U-shaped region of one of the grooves 12 is located in the first U-shaped region of another one of the grooves 12 and is closely surrounded by the first and second linear portions 122, 123 and the first arched portion 126 of the another one of the grooves 12.

The two heat pipes 20 are flat and similar in configuration to the grooves 12 of the base 10. Each heat pipe 20 comprises a first linear section 122, a second linear section 23, a third linear section 24, a first arched section 26 and a second arched section 28. The heat pipes 20 are fittingly accommodated in the corresponding grooves 12 of the base 10, with the first, second, third linear sections 22, 23, 24 thereof received in corresponding first, second, third linear portions 122, 123, 124 of the grooves 12 and with the first, second arched sections 26, 28 thereof received in first, second arched portions 126, 128 of the grooves 12. As a result the first linear sections 22 of the heat pipes 20 are located at the central portion of the base 10, the second, third linear sections 23, 24 are located at corresponding lateral parts of the base 10. Upper surfaces (not labeled) of the heat pipes 20 are flat and share a same plane with the top surface of the base 10.

The fins 30 are stacked in a direction along the parallel linear portions 122, 123, 124 of the grooves 12. Each of the fins 30 is substantially rectangular and is made from a metal sheet. Each fin 30 is parallel to and spaced with a predetermined distance from an adjacent fin 30. Each fin 30 has a flange (not label) extending perpendicularly from a lower end thereof. The flanges of all the fins 30 cooperate to define a plane, for facilitating positioning of the fins 30 relative to the base 10. The fins 30 are arranged on the base 10 extending in a direction perpendicular to the top surface of the base 10, and with the flanges soldered to the upper surfaces of the heat pipes 20 and the top surface of the base 10. Thus the fins 30 are kept in thermal contact with both the base 10 and the heat pipes 20.

In use of the heat dissipation device in accordance with this embodiment of the invention, a centre of the base 10 absorbs heat from the electronic device to which the base 10 is attached. The first linear portions 22 of the heat pipes 20 absorb the heat accumulated in the centre of the base 10 and spreads the heat to other parts of the base 10 via the first, second arched sections 26, 28 and the second, third linear sections 23, 24. The heat is thus symmetrically and evenly distributed on the base 10 and conducted to the fins 30 from both the base 10 and the heat pipes 20 simultaneously. The heat in the fins 30 is subsequently dissipated to ambient air.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device adapted for removing heat from an electronic device, the heat dissipation device comprising:
a base adapted for thermally engaging with the electronic device, the base having a top face and defining two sinuous grooves in the same side as the top face is located;
two flat heat pipes fittingly received in the grooves of the base; and
a plurality of fins arranged on the top surface of the base and the flat heat pipes;
wherein each of the grooves encloses a first U-shaped region and a second U-shaped region which is smaller than the first U-shaped region, the first and second U-shaped regions have opposite orientations, the second U-shaped region of one of the grooves is located in the first U-shaped region of another one of the grooves.

2. The heat dissipation device of claim 1, wherein upper surfaces of the flat heat pipes share a plane with the top face of the base.

3. The heat dissipation device of claim 1, wherein each of the grooves comprises parallel and separate first, second and third linear portions and first and second arched portions connecting the first, second and third linear portions, and wherein the first and second U-shaped regions are enclosed by the linear and arched portions respectively.

4. The heat dissipation device of claim 3, wherein a distance from the first linear portion to the second linear portion is longer than that from the first linear portion to the third linear portion, and wherein in each of the grooves, the first and second linear portions and the first arched portions enclose the first U-shaped region, and the first and third linear portions and the second arched portions enclose the second U-shaped region.

5. The heat dissipation device of claim 3, wherein the linear portions of each of the grooves are extended in a direction perpendicular to a length of each of the fins.

6. The heat dissipation device of claim 3, wherein the second arched portion of one of the grooves is closely surrounded by the first arched portion of another one of the grooves.

7. The heat dissipation device of claim 3, wherein the first linear portions of the grooves span a centre of the base, and the second and third linear portions of the grooves are located adjacent to lateral sides of the base.

8. A heat dissipation device comprising:
a base adapted for thermally engaging with the electronic device, the base having a top face and defining S-shaped first grooves at the top face;
a plurality of fins arranged on the base; and
a first flat heat pipe fittingly received in the first groove of the base wherein the S-shaped first grooves are each comprise parallel and separate first, second and third linear portions and first, second arched sections connecting the linear portions together.

9. The heat dissipation device of claim 8, wherein upper surfaces of the flat heat pipes share a plane with the top face of the base.

10. The heat dissipation device of claim 8, wherein the base further defines another second groove similar to the first groove, neighboring and opposite to the first groove and fittingly receiving a second heat pipe.

11. The heat dissipation device of claim 10, wherein a distance from the first linear portion to the second linear portion is longer than that from the first linear portion to the third linear portion, and wherein in each of the grooves, the first and second linear portions and the first arched portions enclose the first U-shaped region, the first and third linear portions and the second arched portions enclose the second U-shaped region.

12. The heat dissipation device of claim 10, wherein the linear portions of each of the grooves are extended in a direction perpendicular to a length of each of the fins.

13. The heat dissipation device of claim 10, wherein the second arched portion of one of the grooves is closely surrounded by the first arched portion of another one of the grooves.

14. The heat dissipation device of claim 10, wherein the first linear portions of the grooves span a centre of the base, and the second and third linear portions of the grooves are located adjacent to lateral sides of the base.

15. A heat dissipation device comprising:
a base having a bottom face adapted for thermally connecting with a heat-generating electronic component and a top face opposite the bottom face;
a plurality of serpentine heat pipes embedded in the top surface of the base wherein the heat pipes are juxtaposed to each other; and
a plurality of fins mounted on the top face of the base and thermally connecting with the base and the heat pipes.

16. The heat dissipation device of claim 15, wherein each of the heat pipes has a first linear portion located at a center of the top face of the base and second and third liner portions located near two opposite sides of top face of the base, respectively.

17. The heat dissipation device of claim 16, wherein the bottom face has a center corresponding to the center of the top face, adapted for thermally connecting with the heat-generating electronic component.

18. the heat dissipation device of claim 17, wherein the heat pipes each have a flat cross section.
